(19) United States
(12) Patent Application Publication
(10) Pub. No.: US 2025/0006243 A1
(43) Pub. Date: Jan. 2, 2025

(54) APPARATUSES AND METHODS FOR ACCESS BASED TARGETED REFRESH OPERATIONS

(71) Applicant: MICRON TECHNOLOGY, INC., Boise, ID (US)

(72) Inventors: Yuan He, Boise, ID (US); Takamasa Suzuki, Tokyo (JP)

(73) Assignee: MICRON TECHNOLOGY, INC., Boise, ID (US)

(21) Appl. No.: 18/829,734

(22) Filed: Sep. 10, 2024

Related U.S. Application Data
(62) Division of application No. 17/731,645, filed on Apr. 28, 2022, now Pat. No. 12,112,787.

(51) Int. Cl. G11C 11/406; G11C 11/408

(52) U.S. Cl. CPC G11C 11/40622; G11C 11/40615; G11C 11/4085

(57) ABSTRACT

Apparatuses, systems, and methods for access based targeted refresh operations. A memory bank has a first sub-bank and a second sub-bank. A refresh control circuit detects an aggressor in one of the sub-banks. Responsive to an access in the other sub-bank, the refresh control circuit performs a targeted refresh operation based on the sub-bank based on the aggressor address.

### CROSS REFERENCE TO RELATED APPLICATION(S)

This application is a divisional of U.S. patent application Ser. No. 17/731,645 filed Apr. 28, 2022. The aforementioned application is incorporated herein by reference, in its entirety, for any purpose.

### BACKGROUND

This disclosure relates generally to semiconductor devices, and more specifically to semiconductor memory devices. In particular, the disclosure relates to volatile memory, such as dynamic random access memory (DRAM). Information may be stored on individual memory cells of the memory as a physical signal (e.g., a charge on a capacitive element). When accessed, the memory cell may be coupled to a digit line (or bit line), and a voltage on the digit line may change based on the information stored in the coupled memory cell.

In volatile memory devices, the information may decay over time. To prevent information from being refreshed, the information may be periodically refreshed (e.g., by restoring the charge on a memory cell to an initial level). However, refresh operations may require time which could have otherwise been used for access operations in the memory.

### BRIEF DESCRIPTION OF THE DRAWINGS

FIG. 1 is a block diagram of a semiconductor device according an embodiment of the disclosure.

FIG. 2A is a block diagram of refresh logic according to some embodiments of the present disclosure.

FIG. 2B is a block diagram of refresh operations according to some embodiments of the present disclosure.

FIG. 3 is a timing diagram of refresh operations in a memory according to some embodiments of the present disclosure.

FIG. 4 is a block diagram of refresh logic according to some embodiments of the present disclosure.

FIG. 5 is a timing diagram of refresh operations according to some embodiments of the present disclosure.

FIG. 6 is a flow chart of a method according to some embodiments of the present disclosure.

### DETAILED DESCRIPTION

The following description of certain embodiments is merely exemplary in nature and is in no way intended to limit the scope of the disclosure or its applications or uses. In the following detailed description of embodiments of the present systems and methods, reference is made to the accompanying drawings which form a part hereof, and which are shown by way of illustration specific embodiments in which the described systems and methods may be practiced. These embodiments are described in sufficient detail to enable those skilled in the art to practice presently disclosed systems and methods, and it is to be understood that other embodiments may be utilized and that structural and logical changes may be made without departing from the spirit and scope of the disclosure. Moreover, for the purpose of clarity, detailed descriptions of certain features will not be discussed when they would be apparent to those with skill in the art so as not to obscure the description of embodiments of the disclosure. The following detailed description is therefore not to be taken in a limiting sense, and the scope of the disclosure is defined only by the appended claims.

Memory arrays may generally include a number of memory cells arranged at the intersection of word lines (rows) and bit lines/digit lines (columns). To prevent information from being lost, the memory may refresh memory cells on a row-by-row basis (or in sets of rows). Over the course a refresh cycle, the memory may refresh the memory cells as part of sequential refresh operations. The memory may have a refresh period, tREFI, which determines the maximum timing between refresh operations in order to ensure that all memory cells are refreshed over the course of a refresh cycle. For example, tREFI may be based on the expected time at which any individual memory cell needs to be refreshed divided by a total number of refresh operations in a refresh cycle (e.g., a number of rows or a number of rows refreshed per refresh operation). The refresh period tREFI may be relatively short (e.g., <10 μsec). The memory may refresh a first word line (or a first set of word lines) as part of a first sequential refresh operation, then refresh a second word line (or set of word lines) as part of a second sequential refresh operation and so forth until all word lines have been refreshed, then may restart from the beginning of the sequence.

Certain access patterns to the memory may change a rate at which information decays in the memory cells. For example, a row hammer may be repeated access to an ‘aggressor’ row of the memory, which may increase a rate of information decay in memory cells along nearby ‘victim’ word lines. Since the information in the victim word lines may decay faster than the assumptions used to calculate tREFI, it may be important to identify aggressors, and perform targeted refresh operations on the victims of those identified aggressors. In conventional memories, refresh operations may be called for every tREFI. Targeted refresh operations may ‘steal’ a timeslot which is otherwise set aside for a sequential refresh operation. However, this may inefficient, as targeted refresh operations need only be performed when an aggressor has been detected. Accordingly, conventional memories may include relatively logic which manages when to perform targeted refresh operations, what to do if a targeted refresh operation is called for but not aggressor is detected, how to adjust a rate of targeted to sequential refresh operations etc.

The present disclosure is drawn to apparatuses, systems, and methods for access based targeted refresh operations. A memory includes a memory bank which is divided into two or more sub-banks. Each sub-bank is associated with a refresh control circuit which includes an aggressor detector. When an aggressor address is detected in the associated sub-bank, the next time a word line is accessed in a different sub-bank, a targeted refresh operation is performed on the victims of the detected aggressor. In this manner, targeted refresh operations may occur ‘as needed’ in the sub-banks with timing based on accesses in the other sub-banks. This may simplify the logic for determining when to perform targeted refresh operations.

In some embodiments, the use of access operations in other sub-banks to control the timing of targeted refresh operations may be advantageous. Some memories may track accesses to each row of the memory to determine which rows are aggressors. For example, each row may have memory cells set aside which store an access count associated with that row. Based on the access count (e.g., a comparison to a threshold), the row may be determined to be an aggressor. When a targeted refresh operation is performed on the victims of that row, the count value should be reset, which requires accessing the aggressor row (to read, modify and write the count value). However, this requires time to access the aggressor row. After targeted refresh operations have refreshed the victims of the aggressor, the aggressor row may be accessed and it's count value reset responsive to a word line being accessed in a different sub-bank. This may allow the count value along the aggressor to be reset without interrupting normal access operations.

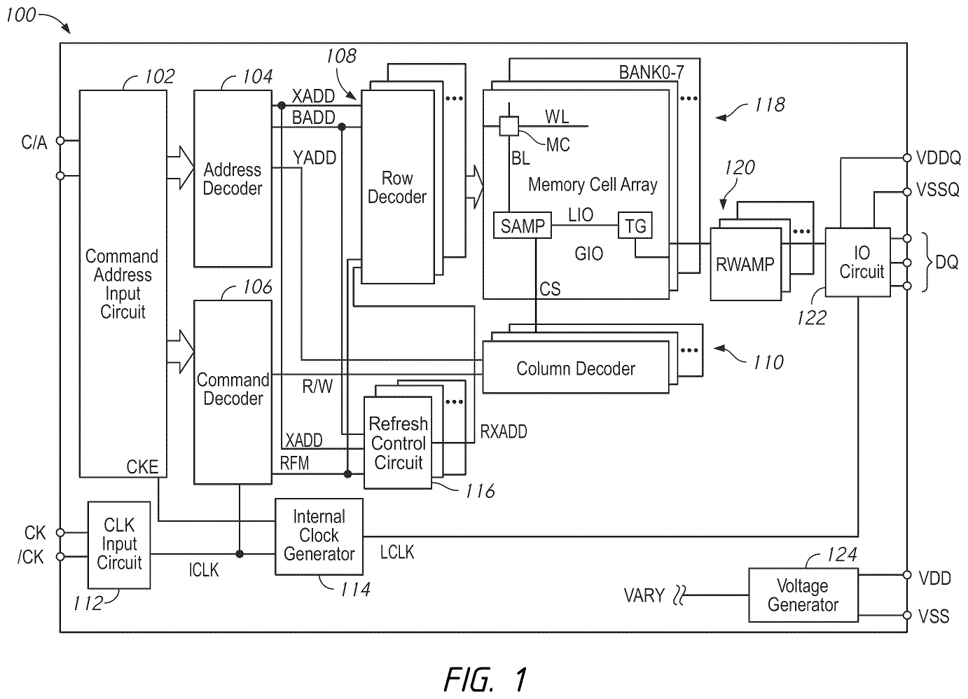

FIG. 1 is a block diagram of a semiconductor device according an embodiment of the disclosure. The semiconductor device 100 may be a semiconductor memory device, such as a DRAM device integrated on a single semiconductor chip.

The semiconductor device 100 includes a memory array 118. The memory array 118 is shown as including a plurality of memory banks. In the embodiment of FIG. 1, the memory array 118 is shown as including eight memory banks BANK0-BANK7. More or fewer banks may be included in the memory array 118 of other embodiments. As explained in more detail herein, each bank may be further divided into two or more sub-banks. While embodiments where each bank includes two sub-banks are generally described herein, other embodiments may include more sub-banks per bank.

Each memory sub-bank includes a plurality of word lines WL, a plurality of bit lines BLT, and a plurality of memory cells MC arranged at intersections of the plurality of word lines WL and the plurality of bit lines BL. The selection of the word line WL is performed by a row decoder 108 and the selection of the bit lines BL is performed by a column decoder 110. In the embodiment of FIG. 1, the row decoder 108 includes a respective row decoder for each memory bank and the column decoder 110 includes a respective column decoder for each memory bank. In some embodiments, components such as the row and column decoders and refresh control circuit 116 which are repeated on a per-bank basis may also include components which are repeated on a per-sub-bank basis. For example, there may be a refresh control circuit 116 for each sub-bank.

The bit lines BL are coupled to a respective sense amplifier (SAMP). Read data from the bit line BL is amplified by the sense amplifier SAMP, and transferred to read/write amplifiers 120 over local data lines (LIO), transfer gate (TG), and global data lines (GIO). Conversely, write data outputted from the read/write amplifiers 120 is transferred to the sense amplifier SAMP over the complementary main data lines GIO, the transfer gate TG, and the complementary local data lines LIO, and written in the memory cell MC coupled to the bit line BL.

The semiconductor device 100 may employ a plurality of external terminals, such as solder pads, that include command and address (C/A) terminals coupled to a command and address bus to receive commands and addresses, clock terminals to receive clocks CK and /CK, data terminals DQ coupled to a data bus to provide data, and power supply terminals to receive power supply potentials VDD, VSS, VDDQ, and VSSQ.

The clock terminals are supplied with external clocks CK and/CK that are provided to an input circuit 112. The external clocks may be complementary. The input circuit 112 generates an internal clock ICLK based on the CK and/CK clocks. The ICLK clock is provided to the command decoder 106 and to an internal clock generator 114. The internal clock generator 114 provides various internal clocks LCLK based on the ICLK clock. The LCLK clocks may be used for timing operation of various internal circuits. The internal data clocks LCLK are provided to the input/output circuit 122 to time operation of circuits included in the input/output circuit 122, for example, to data receivers to time the receipt of write data. The input/output circuit 122 may include a number of interface connections, each of which may be couplable to one of the DQ pads (e.g., the solder pads which may act as external connections to the device 100).

The C/A terminals may be supplied with memory addresses. The memory addresses supplied to the C/A terminals are transferred, via a command/address input circuit 102, to an address decoder 104. The address decoder 104 receives the address and supplies a decoded row address XADD to the row decoder 108 and supplies a decoded column address YADD to the column decoder 110. The column decoder 110 may provide a column select signal CS, which may activate a selected one of the sense amplifiers SAMP. The address decoder 104 may also supply a decoded bank address BADD, which may indicate the bank of the memory array 118 containing the decoded row address XADD and column address YADD. The row address XADD may indicate the sub-bank within the bank indicated by BADD.

The C/A terminals may be supplied with commands. Examples of commands include timing commands for controlling the timing of various operations, access commands for accessing the memory, such as read commands for performing read operations and write commands for performing write operations, as well as other commands and operations. The access commands may be associated with one or more row address XADD, column address YADD, and bank address BADD to indicate the memory cell(s) to be accessed.

The commands may be provided as internal command signals to a command decoder 106 via the command/address input circuit 102. The command decoder 106 includes circuits to decode the internal command signals to generate various internal signals and commands for performing operations. For example, the command decoder 106 may provide a row command signal to select a word line and a column command signal to select a bit line.

The device 100 may receive an access command which is a read command. When a read command is received, and a bank address, a row address and a column address are timely supplied with the read command, read data is read from memory cells in the memory array 118 corresponding to the row address and column address. The read command is received by the command decoder 106, which provides internal commands so that read data from the memory array 118 is provided to the read/write amplifiers 120. The read data is provided along the data bus and output to outside from the data terminals DQ via the input/output circuit 122.

The device 100 may receive an access command which is a write command. When the write command is received, and a bank address, a row address and a column address are timely supplied with the write command, write data supplied to the data terminals DQ is provided along the data bus and written to a memory cells in the memory array 118 corresponding to the row address and column address. The write command is received by the command decoder 106, which provides internal commands so that the write data is received by data receivers in the input/output circuit 122. Write clocks may also be provided to the external clock terminals for timing the receipt of the write data by the data receivers of the input/output circuit 122. The write data is supplied via the input/output circuit 122 to the read/write amplifiers 120, and by the read/write amplifiers 120 to the memory array 118 to be written into the memory cell MC.

The device 100 includes refresh control circuits 116, each associated with a bank or sub-bank of the memory array 118. Each refresh control circuit 116 may determine when to perform a refresh operation on the associated sub-bank. The refresh control circuit 116 provides a refresh address RXADD (along with one or more refresh signals, not shown in FIG. 1). The row decoder 108 performs a refresh operation on one or more word lines associated with RXADD.

The refresh control circuit 116 may perform multiple types of refresh operation, which may determine how the address RXADD is generated, as well as other details such as how many word lines are associated with the address RXADD. For example, the refresh control circuit 116 may perform sequential refresh operations, where the refresh address RXADD is generated based on a sequence of refresh operations. For example, after a first sequential refresh operation with an address RXADD, the next sequential refresh operation may generate an address RXADD+1. Sequential refresh addresses may be associated with multiple word lines, for example by truncating the address RXADD compared to a full row address XADD, and refreshing all word lines which share the truncated portion in common. Over the course of a refresh cycle, the sequential refresh operations may refresh all word lines in the sub array (e.g., by sequentially generating addresses associated with all word lines) and then the sequence may recycle.

The refresh control circuit 116 may perform sequential refresh operations with timing based on a refresh interval tREFI. The refresh interval tREFI may be based on expected timing for refreshing any given word line (e.g., based on an expected rate of information decay) as well as the number of refresh operations required to complete a refresh cycle (e.g., the number of sequential refresh operations per refresh cycle). Each tREFI, the refresh control circuit 116 may perform a sequential refresh operation. For example, a refresh signal REF may be generated each time tREFI elapses and responsive to the refresh signal REF, one or more sequential refresh operations may be performed.

As well as sequential refresh operations, the refresh control circuit 116 may perform targeted refresh operations, where the refresh address RXADD is based on a detected aggressor word line. Certain access patterns to a row may cause an increased rate of data decay in the memory cells of other nearby rows. For example, multiple accesses to a single row, a ‘row hammer’, may increase the rate of decay in memory cells along the nearby word lines. Since these memory cells may decay faster than the timing expected by tREFI, it is useful to identify these aggressor rows so that their victims can be refreshed.

The refresh control circuit may include logic which detects aggressors and then generates a refresh address RXADD based on the detected aggressor as part of a targeted refresh operation. For example, if the aggressor is AggXADD, then the refresh control circuit may refresh adjacent and/or nearby word lines such as one or more of AggXADD+1, AggXADD−1, AggXADD+2, AggXADD−2, etc. Various criterion may be used to detect aggressors. For example, the memory may count a number of accesses to different word lines (e.g., based on the row addresses XADD which are provided along a row address bus from the address decoder 104) and designate a row address as an aggressor when that count crosses a threshold. In some embodiments, the count of accesses to a given row may be stored along memory cells of that row. Accordingly, when a word line is accessed, the count may be read from the memory cells of that row, modified (e.g., incremented), compared to a threshold, and the changed count (e.g., either incremented or reset if the count was above the threshold) may be written back.

While the present disclosure may generally refer to detecting aggressor addresses and their victims, it should be understood that these term are used to mean rows which are used to calculate targeted refresh addresses. For example, it is not necessary that the aggressor address undergo an attack, such as a row hammer, or that there is actual increased data decay in the victims. In some embodiments, the memory may use sampling, which may introduce an aspect of randomness into the selection of aggressor addresses.

The refresh control circuit 116 may perform targeted refresh operations on a sub-bank with timing based, in part, on accesses to other sub-banks of the same bank. For example, if there are two sub-banks per bank, after an aggressor is detected in a second sub-bank when a word line is accessed in the first sub-bank, the refresh control circuit 116 may refresh one or more victims in the second sub-bank based on the detected aggressor. In this manner, targeted refresh commands may be performed in an ‘on-demand’ fashion, with timing based on accesses to different sub-banks

The refresh control circuit 116 may also receive refresh management RFM commands which may cause the refresh control circuit 116 to perform a targeted refresh operation. The RFM command may be issued by a controller external to the device 100.

The power supply terminals are supplied with power supply potentials VDD and VSS. The power supply potentials VDD and VSS are supplied to an internal voltage generator circuit 124. The internal voltage generator circuit 124 generates various internal potentials VARY, and the like based on the power supply potentials VDD and VSS supplied to the power supply terminals.

The power supply terminals are also supplied with power supply potentials VDDQ and VSSQ. The power supply potentials VDDQ and VSSQ are supplied to the input/output circuit 122. The power supply potentials VDDQ and VSSQ supplied to the power supply terminals may be the same potentials as the power supply potentials VDD and VSS supplied to the power supply terminals in an embodiment of the disclosure. The power supply potentials VDDQ and VSSQ supplied to the power supply terminals may be different potentials from the power supply potentials VDD and VSS supplied to the power supply terminals in another embodiment of the disclosure. The power supply potentials VDDQ and VSSQ supplied to the power supply terminals are used for the input/output circuit 122 so that power supply noise generated by the input/output circuit 122 does not propagate to the other circuit blocks.

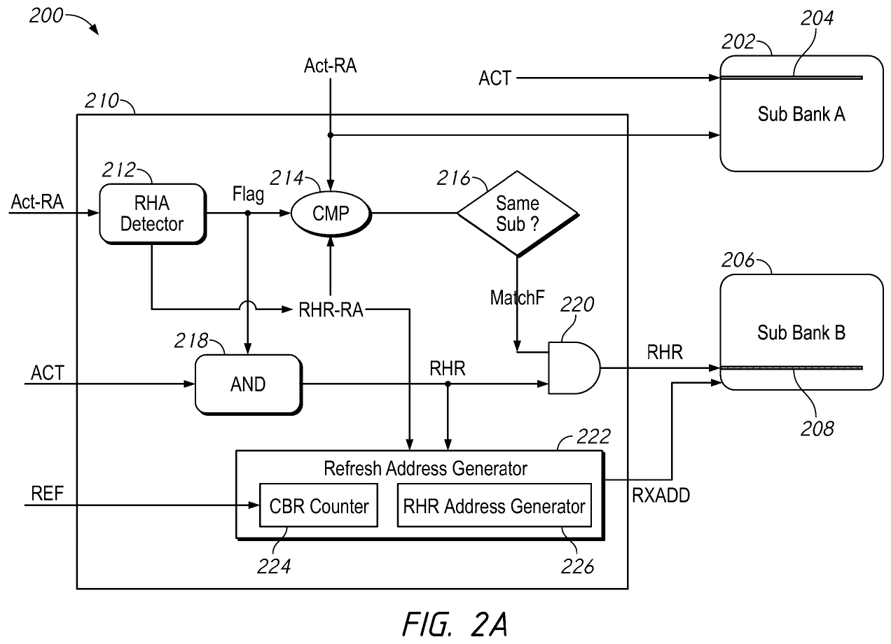

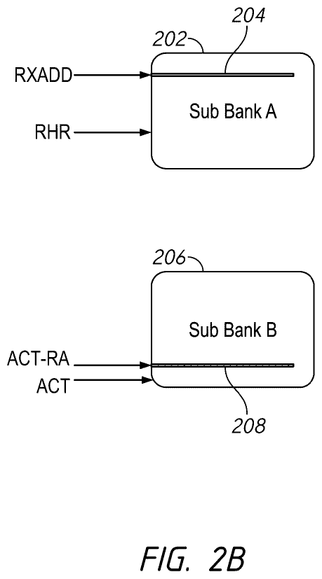

FIG. 2 is a block diagram of refresh logic according to some embodiments of the present disclosure. The refresh logic may represent a portion of a memory device, such as the device 100 of FIG. 1, in some embodiments. The refresh logic 200 includes a refresh control circuit 210 (e.g., 116 of FIG. 1) and a pair of sub-banks 202 and 206, which are part of a same memory bank (e.g., one of the memory banks of the array 118 of FIG. 1). Once the refresh control circuit 210 has detected an aggressor address in one of the sub-banks, then when a word line is accessed in the other sub-bank, a targeted refresh may be performed. In the example of FIG. 2, a refresh control circuit 210 associated with the second sub-bank 206 is shown. Each sub-bank may have a similar refresh control circuit.

The refresh control circuit 210 includes an aggressor detector circuit 212 which activates a flag when an aggressor address RHR-RA has been detected in the associated sub-bank 206. Responsive to an activation command ACT, a logic circuit 218 may provide a targeted refresh signal RHR if the flag is active. If the flag is active, a comparator 214 may determine if the accessed row address Act-RA matches the aggressor RHR-RA, and if it does not, then sub-bank logic 216 may determine if the address Act-RA and RHR-RA are in a same sub-bank (e.g., is Act-RA in sub-bank B 206). If they are not, the sub-bank logic 216 provides a complimentary match signal matchF at an active level. If both the RHR command and matchF are active, then a logic circuit 220 may provide the RHR command to the sub-bank 206. A refresh address generator 222 provides one or more refresh addresses RXADD responsive to either a refresh command REF or the RHR command. If the RHR command is active, then the refresh address generator 222 may generate refresh address(es) based on RHR-RA. Responsive to the RHR command from logic circuit 220, a row decoder (not shown) may refresh one or more word lines associated with RXADD in the sub-bank 206.

The aggressor detector circuit 212 may detect aggressor addresses in the sub-bank 206 based on one or more criteria. For example, the aggressor detector circuit 212 may count accesses to different addresses and if an access count crosses a threshold may determine that address to be an aggressor. In some embodiments, the aggressor detector 212 may receive the accessed address Act-RA and use that to detect an aggressor. In some embodiments, the access counts may be stored in the memory array (e.g., along memory cells of the row associated with that memory count), and the aggressor detector may receive those counts when the row is accessed. Various other techniques to determine aggressor addresses may be used in other example embodiments. When the aggressor detector circuit 212 detects an aggressor it may activate a flag and provide the aggressor address as RHR-RA.

During an example access operation, a command decoder (e.g., 106 of FIG. 1) provides an activation signal ACT while an address decoder (e.g., 104 of FIG. 1) provides an accessed address Act-RA. The address Act-RA may be associated with a word line 204 in the first sub-bank. Responsive to the address Act-RA and the activation signal ACT, the word line 204 is accessed.

A comparator circuit 214 may receive the flag and the RHR-RA from the aggressor detector 212 as well as an accessed address Act-RA. If the flag is active (e.g., if there is a detected aggressor) then the comparator 214 may compare the address RHR-RA and Act-RA to determine if they are the same. If they are not the same, then a sub-bank logic circuit 216 may determine if the address Act-RA is in the sub-bank associated with the refresh control circuit 210. For example, the logic 216 may check a portion of the row address Act-RA which specifies a sub-bank to determine if the address Act-RA is associated with sub-bank B 206. IF the address is not associated with sub-bank B, then the logic 216 provides a signal matchF at an active level (e.g., at a high logical level).

A logic circuit 218 receives the activation command ACT (e.g., from a command decoder) and the flag signal from the aggressor detector 212. If the flag signal is active (e.g., if an aggressor has been detected) then the logic circuit may provide an RHR command. For example, the logic 218 may be an AND gate with inputs coupled to flag and to ACT. A second logic circuit 220 may provide the RHR command to the sub-bank (or to a row decoder associated with the sub-bank) when both the signal matchF and the RHR command are active. For example, the second logic circuit 220 may also be an AND gate with input terminals coupled to RHR from the first logic circuit 218 and to matchF from the sub-bank logic 216. If both are active, then the RHR command is provided to the sub-bank 206.

The refresh logic 210 includes a refresh address generator 222. The refresh address generator 222 includes a CBR counter circuit 224 which generates sequential refresh addresses as the refresh address RXADD when a refresh signal REF is active and a targeted refresh address generator 226 which generates a targeted refresh address as the refresh address RXADD when a targeted refresh signal RHR is active. Responsive to a refresh signal REF, the CBR counter circuit 224 may provide a refresh address RXADD as part of a sequential refresh operation. For example, the CBR counter circuit 224 may updates an address and provides it as the refresh address RXADD as part of a sequential refresh operation. For example, a previous sequential refresh address may be incremented by the CBR counter circuit 224 to generate a new sequential refresh address. In some embodiments, the refresh address generator 222 may provide multiple addresses and perform multiple sequential refresh operations responsive to the signal REF. In some embodiments, the refresh control circuit 210 may perform different numbers of sequential refresh operations responsive to activations of REF. For example, the refresh control circuit 210 may alternate between two sequential refresh operations and one sequential refresh operation.

The targeted refresh address generator 226 may provide a targeted refresh address RXADD based on the aggressor address RHR-RA when the signal RHR is provided. For example, the address RXADD may represent a word line which near to a word line associated with RHR-RA. For example the address RXADD may be one of the word lines adjacent to RHR-RA (e.g., RHR-RA+1 and RHR-RA−1). Other relationships may also be used. In some embodiments, the refresh address generator 222 may provide multiple refresh addresses RXADD responsive to the signal RHR (e.g., both RHR-RA+1 and RHR-RA−1).

Responsive to the signal RHR, a word line associated with RXADD is refreshed in the sub-bank 206. For example, a word line 208 may be refreshed. In this manner, a targeted refresh operation may be performed on the word line 208 in the second sub-bank 206 while the word line 204 in the first sub-bank 202 is being accessed. After refreshing the victim(s) of the identified aggressor RHR-RA, the aggressor detector 212 may reset the flag to an inactive (or unset) state.

FIG. 2B is a block diagram of refresh operations according to some embodiments of the present disclosure. FIG. 2A shows refresh logic performing a targeted refresh operation on a second sub-bank when an access operation is performed in a first sub-bank. FIG. 2B shows a subsequent operation which may be performed on the same sub-banks 202 and 206. For the sake of brevity the details of the refresh logic 210 shown in FIG. 2A are not repeated with respect to FIG. 2B. Each of the sub-banks 202 and 206 may be associated with refresh logic similar to the refresh logic 210 of FIG. 2A.

FIG. 2B shows a targeted refresh being performed on the first sub-bank 202 when an access is performed on the second sub-bank 206. For example, an address decoder (e.g., 104 of FIG. 1) may provide an access address ACT-RA, while a command decoder (e.g., 106 of FIG. 1) provides a row activation command ACT. In the situation depicted in FIG. 2B, the address ACT-RA is associated with a word line 208 in a second sub-bank 206. A refresh logic circuit (not shown) associated with the first sub-bank 202 also receives the signals ACT and ACT-RA. Based on a determination that the address ACT-RA is associated with the second sub-bank 206 (and a previous identification of an aggressor in the first sub-bank 202), a refresh address RXADD and refresh signal RHR may be generated. In this manner, a word line 204 in the first sub-bank 202 may be refreshed responsive to a word line 208 in the second sub-bank being accessed.

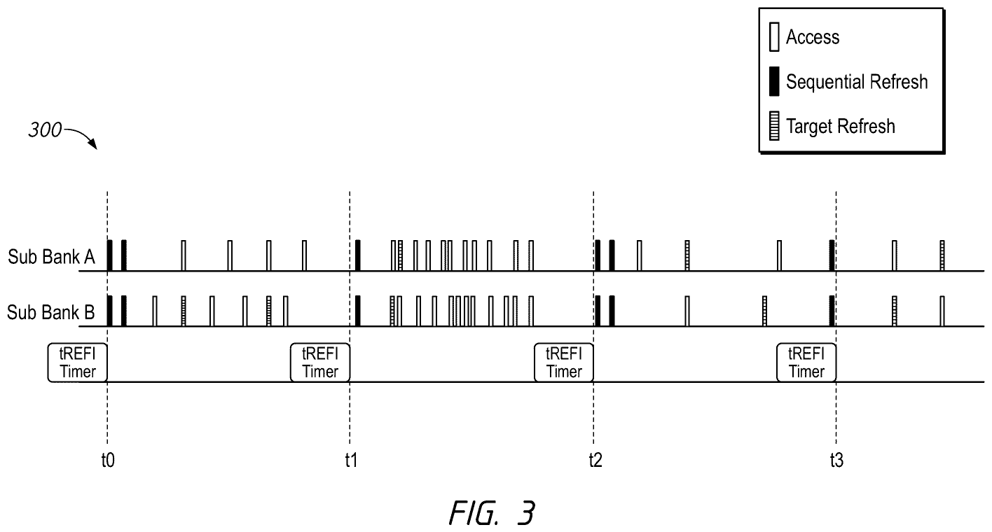

FIG. 3 is a timing diagram of refresh operations in a memory according to some embodiments of the present disclosure. The timing diagram 300 may represent refresh operations in a device such as the memory device 100 of FIG. 1 and/or the refresh logic 200 of FIG. 2.

The timing diagram shows several refresh intervals, beginning at times t0, t1, t2, and t3, each of which is marked by the activation of tREFI timer signal. The different refresh intervals may be separated by a time tREFI, which may be a setting of the memory. In some embodiments, the refresh intervals may be marked by a refresh signal REF (not shown in FIG. 3).

During the first refresh interval beginning at t0, a refresh signal causes two sequential refresh operations to be performed in both sub-banks. Before the time t0, an aggressor address has been detected in sub-bank B, but not in sub-bank A. After t0, a first access is performed in sub-bank B. Since there is no detected aggressor in sub-bank A (e.g., the flag for sub-bank A is inactive/unset), no targeted refresh is performed in sub-bank A responsive to the access in sub-bank B. However, when a row is accessed in sub-bank A, a targeted refresh operation may be performed in sub-bank B. During subsequent accesses to sub-bank B, a second aggressor may be detected. Accordingly, during a later access to sub-bank A, a second targeted refresh may be performed in sub-bank A.

During a second refresh interval beginning at t1, only a single sequential refresh operation may be performed. At the time t1, aggressors have been located in both of the sub-banks. Accordingly, after a first access in the first sub-bank, a targeted refresh is performed in sub-bank B. After a first access in the sub-bank B, a targeted refresh is performed in the sub-bank A. Since no further aggressors are detected in the period between t1 and t2, no further targeted refresh operations are performed.

During a third refresh interval beginning at t2, two sequential refresh operations are performed. After that, an access is performed in the sub-bank A, which is determined to be an aggressor. Accordingly, a next time sub-bank B is accessed, a targeted refresh operation is performed in sub-bank A. Similarly at the refresh period beginning with t3, targeted refresh operations are performed in both sub-banks responsive to access operations in the opposite sub-bank.

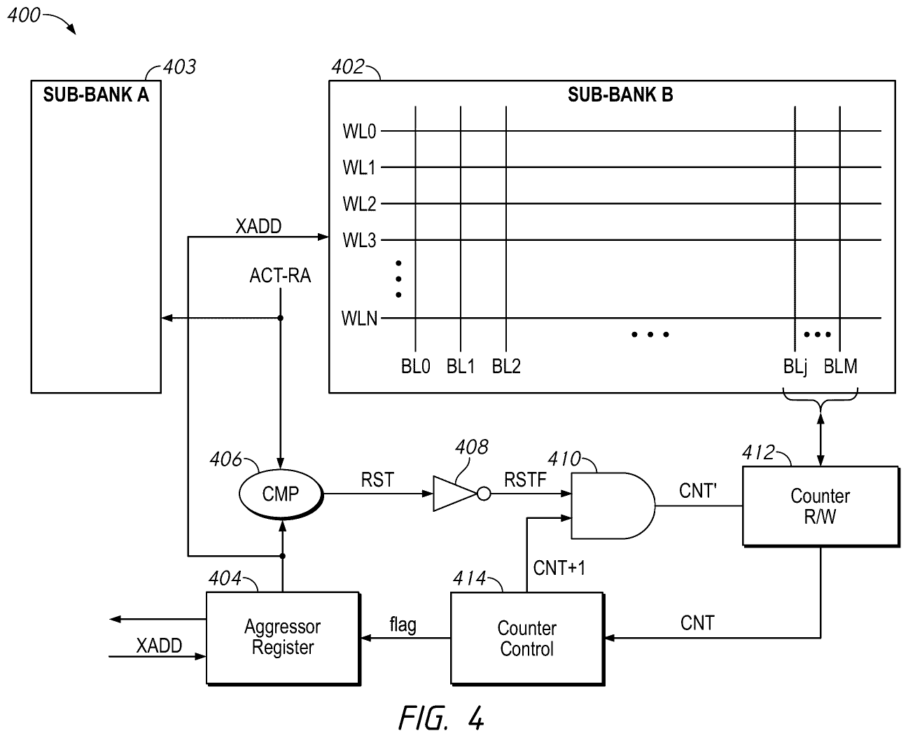

FIG. 4 is a block diagram of refresh logic according to some embodiments of the present disclosure. FIG. 4 shows refresh logic which may be included in the memory device 100 of FIG. 1, and which may implement a portion of the refresh logic 200 of FIG. 2. FIG. 4 shows a sub-bank 402 (e.g., 206 of FIGS. 2A-B) as well as a sub-bank 403 (e.g., 202 of FIGS. 2A-B) and several other components which may be part of a refresh control circuit (e.g., 210 of FIGS. 2A-B).

FIG. 4 shows an example embodiment where access counts used to determine if a row is an aggressor are stored along the rows of the memory array. When that row is accessed, the count may be read out from the word line, changed (e.g., incremented), and compared to a threshold. If it meets or exceeds a threshold it may be judged to be an aggressor, and an aggressor flag (e.g., flag of FIG. 2A) may be set. Responsive to the flag being set, the aggressor address XADD may be stored in an aggressor register (which may be a component of the refresh control circuit 210 of FIG. 2A) and the count value of that row address XADD may be reset. In the embodiment of FIG. 4, the refresh logic 400 may reset the aggressor count performing the targeted refresh responsive to an access in the other sub-bank 403 of the memory.

The refresh logic 400 shows a sub-bank 402 which includes a number of word lines and bit lines. Memory cells (not shown) are located at the intersection of the word and bit lines. Certain memory cells along each row are set aside to store a count value associated with that row. In the example embodiment of FIG. 4, bit lines along the end of word line, the bit line BLj to BLm are used, however other placements may be used in other values. The memory cells at the intersection of the bit lines BLj to BLm with each word line may store a binary number which represents a count of accesses to that word line. The sub-bank 403 may also have a similar structure (e.g., bit lines, word lines, memory cells, count values in memory cells, etc.) but for clarity they are not shown in FIG. 4.

When a word line is accessed (e.g., responsive to the access address ACT-RA and an activation signal ACT), the count value CNT associated with that row may be read out by a counter read/write (R/W) circuit 412. A counter control circuit 414 (which may be part of an aggressor detector circuit such as 212 of FIG. 2) may change the count value. In the example of FIG. 4, the counter control circuit 414 may increment the count (e.g., to CNT+1). The count control circuit 414 compares the updated count value to a threshold. If the updated count value meets or exceeds the threshold, the counter control circuit 414 may set a flag signal (e.g., change the signal flag from logical low to logical high) which indicates that the address ACT-RA is an aggressor.

The changed count value CNT+1 is provided to a logic gate 410, which provides it as a new count value CNT′ to the counter R/W circuit 412 when a reset signal RSTF is at a high logical level. Responsive to receiving an updated count value, the counter R/W circuit 412 writes the updated value CNT′ back to the memory cells of the sub-bank 402.

An aggressor register 404 (e.g., part of a refresh address generator 222 of FIG. 2) receives the flag signal flag and responsive to the signal flag being set (e.g., being changed to an active state) the aggressor register 404 captures a current value of the address XADD along the row address bus. The address XADD may be the address ACT-RA which was accessed and which associated count value crossed the threshold.

A comparator 406 may receive an activation address ACT-RA as part of a subsequent access operation. The comparator 406 compares the address ACT-RA and the stored aggressor address XADD in the aggressor register 404 and determines if they are in the same sub-bank. If they are not (e.g., if ACT-RA is associated with sub-bank 403), then the comparator 406 provides a reset signal RST at an active level. An inverter 408 provides the signal RSTF at a low logical level when the signal RST is at an active level. When the signal RSTF is at a low logical level, the logic gate 410 provides a value of CNT′ which is a reset value. For example, the logic gate 410 may be AND logic, and when the signal RSTF is at a low logical level, the bits of the value CNT′ may be at a low logical level (e.g., the binary number may be 0). Accordingly, when the aggressor register 404 stores an aggressor address XADD in a sub-bank 402, and a subsequent access address is provided associated with a second sub-bank 403, then a reset count value CNT′ is written to the memory cells which store the count along a word line associated with RST-RA (e.g., the aggressor word line). In some embodiments, the comparator 406 may be the same comparison logic used to determine if the aggressor and accessed address are in the same sub-bank (e.g., the comparator 406 may represent the comparator 214 and sub-bank logic 216 of FIG. 2).

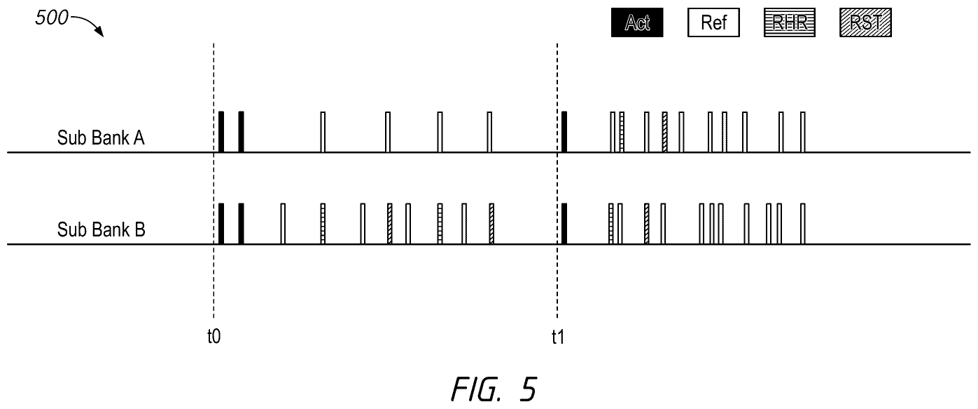

FIG. 5 is a timing diagram of refresh operations according to some embodiments of the present disclosure. The timing diagram 500 may, in some embodiments, represent the operations of refresh logic such as the refresh logic 400 of FIG. 4. The timing diagram 500 may be generally similar to the timing diagram 300 of FIG. 3. For the sake of brevity, features previously described with respect to FIG. 3 will not be described again.

At an initial time t0, a refresh period begins with two sequential refresh operations. Afterwards, an access is performed in sub-bank B, and the access address is identified as an aggressor. When a word line in sub-bank A is performed, a targeted refresh is performed on a victim associated with the aggressor. For the sake of simplicity, in the example of FIG. 5, only a single targeted refresh is performed per aggressor. During a next access in the sub-bank A, the aggressor is accessed so that its count value may be reset as part of a reset operation.

At a first time t1, an aggressor is detected in both sub-banks. During a first access to sub-bank A, a targeted refresh is performed in sub-bank B. Next during an access to sub-bank B a targeted refresh is performed in sub-bank A. Next, sub-bank A is accessed and the aggressor in sub-bank B is reset followed by an access to sub-bank B which allows a reset operation to be performed on the aggressor in sub-bank A.

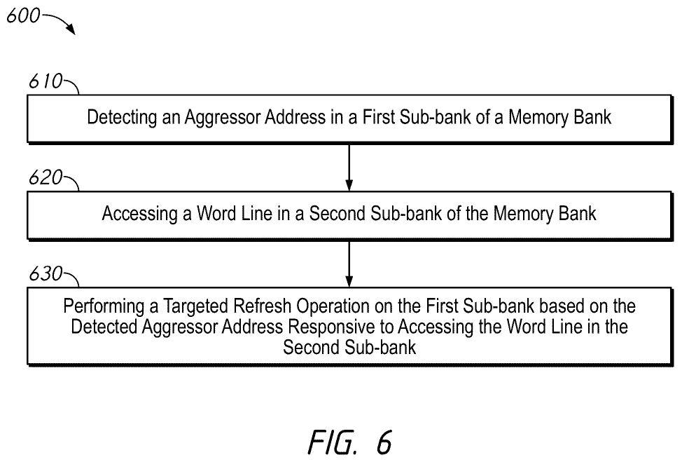

FIG. 6 is a flow chart of a method according to some embodiments of the present disclosure. The method 600 may, in some embodiments, be implemented by one or more of the apparatuses or components thereof described herein, such as the memory device 100 of FIG. 1, the refresh logic 200 of FIG. 2 and/or the refresh logic 400 of FIG. 4.

The method 600 includes block 610, which describes detecting an aggressor address in a first sub-bank of a memory bank. For example, the method 600 may include detecting the aggressor address with an aggressor detector 212 based on accesses to the aggressor address. For example, the method 600 may include counting accesses to accessed addresses and designating an address as the aggressor address when its count meets or exceeds a threshold. In some embodiments, the method 600 may include reading a count value from memory cells of a word line associated with the aggressor address and determining that it's the aggressor based on the count value.

The method 600 includes box 620, which describes accessing a word line in a second sub-bank of the memory bank. For example, an access address ACT-RA may be associated with a word line in the second sub-bank.

The method 600 includes box 630, which describes performing a targeted refresh operation on the first sub-bank based on the detected aggressor address responsive to accessing the word line in the second sub-bank. For example, the method 600 may include generating a refresh address based on the aggressor address and refreshing a word line associated with the refresh address as part of a targeted refresh operation. The method 600 may include performing the targeted refresh operation on the first sub-bank responsive to a next access operation in the second sub-bank after detecting the aggressor address in the first sub-bank. The method 600 may also include performing sequential refresh operations based on a refresh signal which periodically provided.

Of course, it is to be appreciated that any one of the examples, embodiments or processes described herein may be combined with one or more other examples, embodiments and/or processes or be separated and/or performed amongst separate devices or device portions in accordance with the present systems, devices and methods.

Finally, the above-discussion is intended to be merely illustrative of the present system and should not be construed as limiting the appended claims to any particular embodiment or group of embodiments. Thus, while the present system has been described in particular detail with reference to exemplary embodiments, it should also be appreciated that numerous modifications and alternative embodiments may be devised by those having ordinary skill in the art without departing from the broader and intended spirit and scope of the present system as set forth in the claims that follow. Accordingly, the specification and drawings are to be regarded in an illustrative manner and are not intended to limit the scope of the appended claims.

What is claimed is:

1. An apparatus comprising:
a row hammer detector configured to detect an aggressor address and set a row hammer flag when the aggressor address is detected;
a comparator configured to compare the aggressor address to an accessed address and provide an active match signal when the aggressor address and the accessed address are in different sub-banks; and
a logic circuit configured to provide a targeted refresh command responsive to an access command when the match signal is active.

2. The apparatus of claim 1, further comprising a refresh address generator configured to provide a refresh address based on the aggressor address responsive to the targeted refresh command.

3. The apparatus of claim 1, further comprising:
a counter read/write circuit configured to receive a count value from a memory array, wherein the row hammer detector is configured to detect the aggressor address based on the count value.

4. The apparatus of claim 3, wherein the count value is stored in memory cells of a row associated with the count value.

5. The apparatus of claim 3, wherein the row hammer detector is further configured to:
change the count value and compare the changed count value to a threshold; and
responsive to the changed count value meeting or exceeding the threshold, provide the updated count value to the counter read/write circuit, and wherein the counter read/write circuit is further configured to write the updated count value to the memory array.

6. The apparatus of claim 3, further comprising:
a refresh address generator circuit configured to provide a reset address after the targeted refresh command,
wherein the comparator is configured to provide a reset signal when the accessed address is not in the same sub-bank as the reset address, and
wherein the counter read/write circuit is further configured to reset the count value responsive to the reset signal.

7. The apparatus of claim 1, further comprising a memory bank including a first sub-bank and a second sub-bank, wherein the accessed address is associated with the first sub-bank and the aggressor address is associated with the second sub-bank.

8. The apparatus of claim 7, wherein responsive to the accessed address a first word line is accessed in the first sub-bank while responsive to the targeted refresh command a word line is refreshed in the second sub-bank.

9. A method comprising:
detecting an aggressor address and setting a row hammer flag when the aggressor address is detected;
comparing the aggressor address to an accessed address and providing an active match signal when the aggressor address and the accessed address are in different sub-banks; and
providing a targeted refresh command responsive to an access command when the match signal is active.

10. The method of claim 9, further comprising:
providing a refresh address based on the aggressor address responsive to the targeted refresh command.

11. The method of claim 9, further comprising:
detecting the aggressor address based on a count value provided by a memory array.

12. The method of claim 11, further comprising:
changing the count value and comparing the changed count value to a threshold; and
responsive to the changed count value meeting or exceeding the threshold, providing the updated count value to the memory array.

13. The method of claim 11, further comprising:
providing a reset address after the targeted refresh command;
providing a reset signal when the accessed address is not in the same sub-bank as the reset address, and
resetting the count value responsive to the reset signal.

14. The method of claim 9, wherein the accessed address is associated with a first sub-bank of a memory bank and the aggressor address is associated with a second sub-bank of the memory bank.

15. The method of claim 14, wherein responsive to the accessed address a first word line is accessed in the first sub-bank while responsive to the targeted refresh command a word line is refreshed in the second sub-bank.

16. An apparatus comprising:
an aggressor detector circuit configured to activate a flag responsive to detecting an aggressor address in a sub-bank and provide the aggressor address;
a comparator configured to determine if an accessed address matches the aggressor address and issue an active match signal when the aggressor address and the accessed address are in different sub-banks;
a logic circuit configured to provide a targeted refresh signal to the sub-bank responsive to the activated flag; and
a refresh address generator configured to provide a refresh address based on a refresh signal or the targeted refresh signal.

17. The apparatus of claim 16, further comprising a row decoder configured to refresh one or more word lines of the sub-bank based on the refresh address.

18. The apparatus of claim 16, wherein the refresh address generator comprises:
a counter circuit configured to generate sequential refresh addresses as the refresh address when the refresh signal is active; and
a targeted refresh address generator configured to generate a targeted refresh address as the refresh address when the targeted refresh signal is active.

19. The apparatus of claim 18, wherein the sequential refresh addresses are part of a sequential refresh operation on the sub-bank with timing based on a refresh interval.

20. The apparatus of claim 19, wherein aggressor detector circuit is configured to identify the aggressor address based on a count value read from memory cells of the aggressor address.
